(19) United States
(12) Patent Application Publication
(10) Pub. No.: US 2023/0420250 A1
(43) Pub. Date: Dec. 28, 2023

(54) SEMICONDUCTOR DEVICE AND METHOD FOR MANUFACTURING THE SAME

(71) Applicant: Taiwan Semiconductor Manufacturing Company, Ltd., Hsinchu (TW)

(72) Inventors: Bo-Jiun Lin, Hsinchu County (TW); Yu-Chao Lin, Hsinchu City (TW); Tung-Ying Lee, Hsinchu City (TW)

(73) Assignee: Taiwan Semiconductor Manufacturing Company, Ltd., Hsinchu (TW)

(21) Appl. No.: 17/849,720

(22) Filed: Jun. 27, 2022

(51) Int. Cl. H01L 21/02; H01L 29/24; H01L 29/417; H01L 29/76; H01L 29/786; H01L 29/66

(52) U.S. Cl. CPC H01L 21/02568; H01L 21/0262; H01L 21/02631; H01L 29/24; H01L 29/41733; H01L 29/7606; H01L 29/78696; H01L 29/66969

(57) ABSTRACT

A method for manufacturing a semiconductor device includes the following steps. A transition metal layer is formed over a substrate in a reaction chamber; a chalcogen-containing fluid is flowed into the reaction chamber; and a heating process is performed in the reaction chamber over the transition metal layer with the chalcogen-containing fluid to transform the transition metal layer into a two-dimensional (2D) material layer over the substrate.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon.

Transistors are circuit components or elements that are often formed on semiconductor devices. Many transistors may be formed on a semiconductor device in addition to capacitors, inductors, resistors, diodes, conductive lines, or other elements, depending on the circuit design. A field effect transistor (FET) is one type of transistor.

Generally, a transistor includes a gate stack formed between source and drain regions. The source and drain regions may include a doped region of a substrate and may exhibit a doping profile suitable for a particular application. The gate stack is positioned over the channel region and may include a gate dielectric interposed between a gate electrode and the channel region in the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 6B illustrate various plan views and cross-sectional views of a manufacturing process of a semiconductor device in accordance with some embodiments.

FIG. 7 illustrates a schematic cross-section view of a reaction chamber for the manufacturing of a semiconductor device in accordance with some embodiments.

FIG. 8 illustrate a partial enlarged view of the semiconductor device in FIG. 6B.

FIG. 9 illustrate a partial cross-sectional view of a semiconductor device according to some embodiments of the present disclosure.

FIG. 10 illustrate a partial enlarged view of the semiconductor device in FIG. 9.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments such as those described herein provide a semiconductor device by using three dimensional (3D) structures with two dimensional (2D) materials. For example, embodiments such as those described below utilize 3D structures such as trenches and fins formed in a dielectric layer. Generally, 2D materials are monolayers of material held together by chemical bonds. Monolayers may be stacked upon each other to form a 2D material layer comprising individual monolayers. Suitable 2D materials include graphene, transition metal dichalcogenides (TMDs), and boron nitride (BN), and include one to a few (such as less than about monolayers) monolayers of material. For example, individual monolayers of graphene, TMDs may be stacked to create a 2D material layer.

The use of the 3D features with the 2D materials allow formation of the semiconductor devices having a much smaller footprint. For example, a transistor having an 2D material layer may be formed having a larger gate width while requiring a smaller footprint as compared to other types of transistors. Additionally, the use of 2D materials allows the semiconductor device that provide improved gate control.

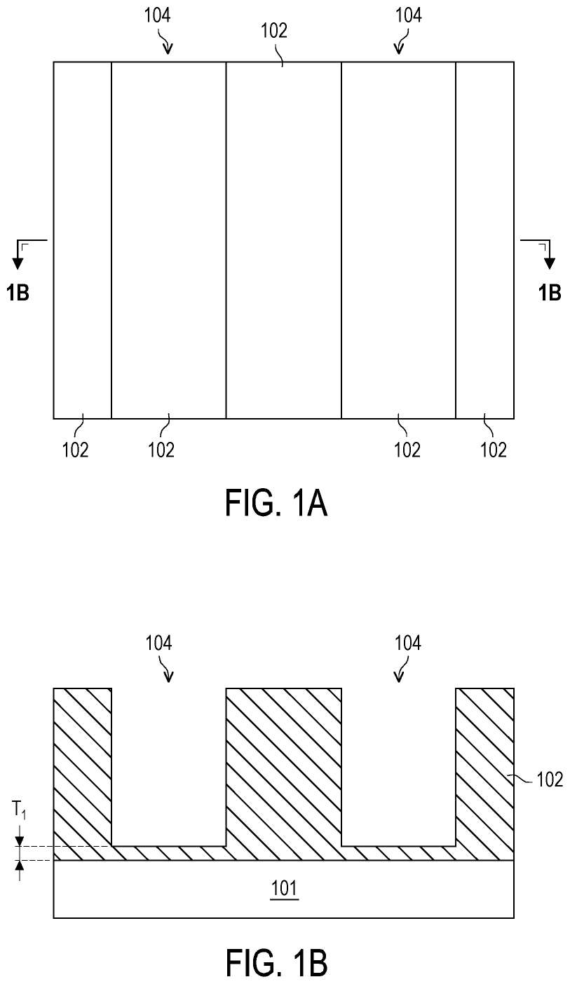

FIG. 1A to FIG. 6B illustrate various plan views and cross-sectional views of a manufacturing process of a semiconductor device in accordance with some embodiments. FIG. 1A to FIG. 6B illustrate the cross-sectional views and plan views, wherein the “A” figures represent the plan view and the “B” figures represent the cross-sectional view along the B-B line of the respective “A” figure.

Referring first to FIG. 1A and FIG. 1B, a portion of a substrate 101 is shown having an insulating layer 102 formed thereon. The substrate 101 may include, for example, bulk silicon, doped or undoped, or an active layer of a semiconductor-on-insulator (SOI) substrate. In some embodiments, depending on the requirements of design, the bulk silicon substrate 101 may be a p-type substrate or an n-type substrate and includes different doped regions. The doped regions may be configured for an n-type FinFET or a p-type FinFET. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as multi-layered or gradient substrates may also be used.

In some embodiments, the insulating layer 102 is formed over the substrate 101. The insulating layer 102 may include an oxide or other dielectric material, for example. The insulating layer 102 may include, for example, silicon oxide, silicon nitride, aluminium oxide, silicon oxynitride, a spin-on dielectric material, any a low-k dielectric material, or the like, and may be formed by, for example, plasma vapor deposition (PVD), high-density-plasma chemical vapor deposition (HDP-CVD), sub-atmospheric CVD (SACVD) or by spin-on or other suitable methods. The insulating layer 102 may be formed to a thickness of about 0.5 μm to about 0.05 μm. Optionally, a chemical mechanical polish process is performed to remove the projected insulating material.

In some embodiments, the insulating layer 102 is patterned to form one or more trenches 104. It is noted that, although two trenches 104 are illustrated herein, but less or more trenches 104 may also be formed depending on actual needs. The disclosure is not limited thereto. As will be explained in greater detail below, vertical transistors will be formed along sidewalls (and/or the bottom) of the trenches. The trenches in the insulating layer 102 may be formed by etching the insulating layer 102 using photolithography techniques. Generally, photolithography involves depositing a photoresist material (not shown), which is then masked, exposed, and developed. After the photoresist mask is patterned, an etching process may be performed to remove unwanted portions of the insulating layer 102 as illustrated in FIG. 1A and FIG. 1B. In an embodiment in which the insulating layer 102 includes SiO₂, the etching process may be a wet dip in dilute hydrofluoric acid, for example. The excess photoresist material may be removed. Additional masks (not shown), e.g., hard masks, may be utilized in the etching process.

As another example, some embodiments form the insulating layer 102 of Al₂O₃ using a physical vapor deposition (PVD) process. In these embodiments, the insulating layer 102 may be etched using, for example, a reactive ion etch (RIE) process using a gas CF₄/O₂, BCl₃, BCl₃/HBr, Cl₂, Cl₂/Ar, or the like.

As illustrated in FIG. 1A and FIG. 1B, a portion of the insulating layer 102 remains over the substrate 101 along a bottom of the trenches 104. That is, the trenches 104 are not extended through the insulating layer 102. This remaining portion of the first insulating layer 102 along the bottom of the trench will allow a selective growth of an overlying 2D material layer. In some embodiments, a thickness T1 of the insulating layer 102 remains along a bottom of the trenches 104 is about 100 nm to about 10 nm, for example.

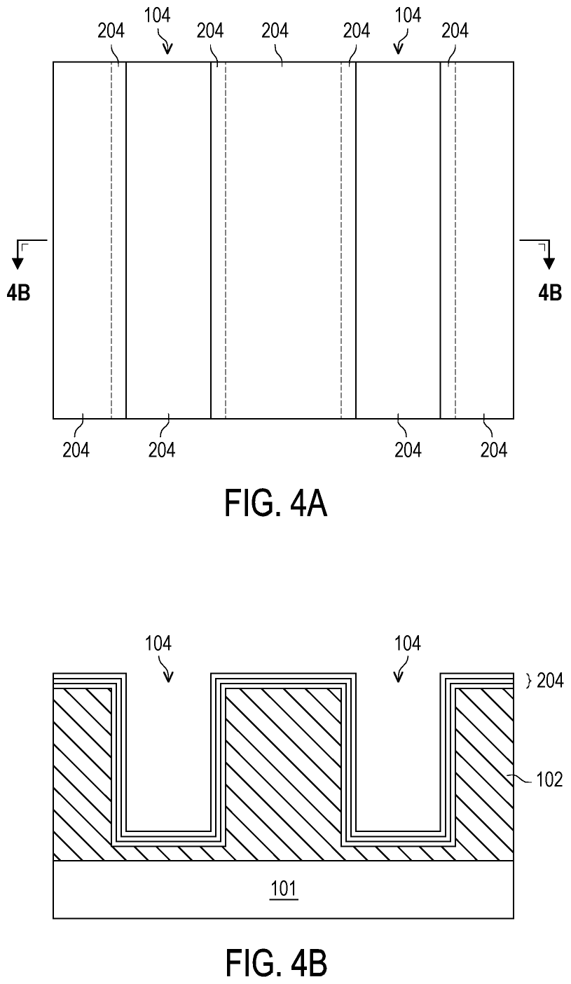

Then, a 2D material layer, i.e., the 2D material layer 204 illustrated in FIG. 4B, may be formed over the insulating layer 102 in accordance with some embodiments. In accordance with some embodiments of the disclosure, the method of forming the 2D material layer 204 may include the following process.

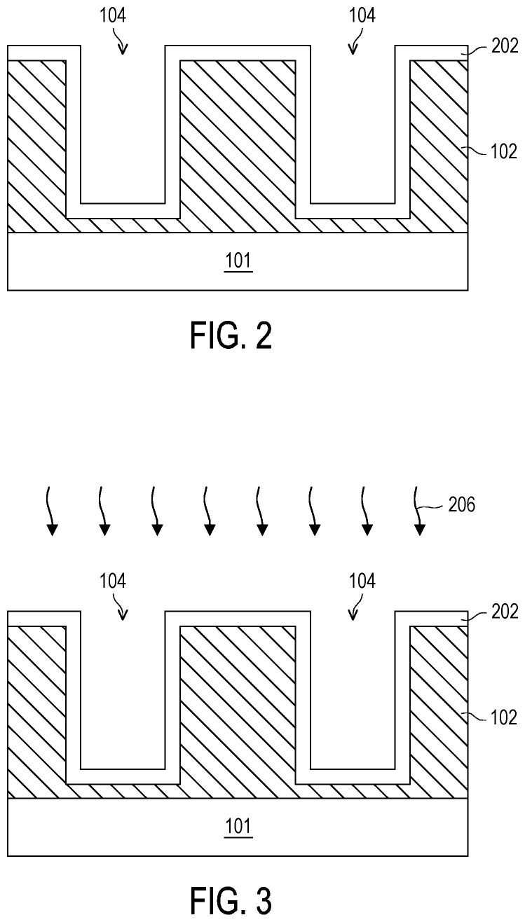

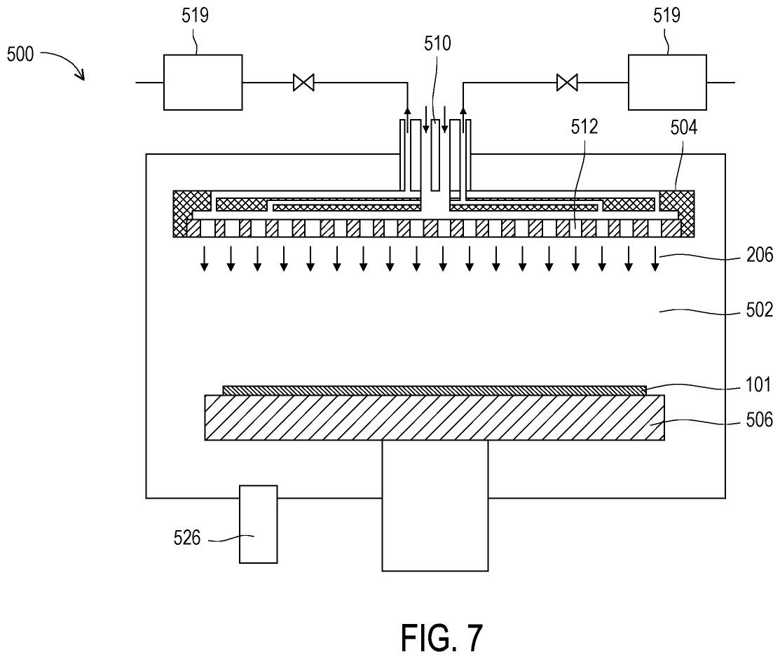

FIG. 7 illustrate a schematic view of a reaction chamber for the manufacturing of a semiconductor device according to some embodiments of the present disclosure. Referring first to FIG. 2 and FIG. 7, a transition metal layer 202 is formed over the insulating layer 102 of the substrate 101 in a reaction chamber 10. In accordance with some embodiments of the disclosure, a transition metal may be defined as an element whose atom has a partially filled d sub-shell, or which can give rise to cations with an incomplete d sub-shell. There are a number of properties shared by the transition metal, which results from the partially filled d sub-shell. These properties include: the formation of compounds whose color is due to d-d electronic transitions; the formation of compounds in many oxidation states due to the relatively low energy gap between different possible oxidation states; and the formation of many paramagnetic compounds due to the presence of unpaired d electrons. In some embodiments, a material of the transition metal layer 202 includes Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), or Palladium (Pd), any combinations thereof, or the like. In some embodiments, the transition metal layer 202 may be formed using, for example, chemical vapor deposition (CVD), physical vapor deposition (PVD), atomic layer deposition (ALD), atmospheric pressure CVD (APCVD), low-pressure CVD (LPCVD) at a sub-atmospheric pressure, plasma enhanced CVD (PECVD), atomic layer CVD (ALCVD), or combinations thereof.

Referring to FIG. 7, in some embodiments, the reaction chamber 500 may include a chamber 502, a shower head 504 and a stage 506 for holding a substrate (i.e., the substrate 101 with the insulating layer 102 as shown in FIG. 1B). The shower head 504 and the stage 506 are configured to be mounted inside chamber 502. The substrate 101 is disposed on stage 506. In some embodiments, the stage 506 is disposed in the chamber 10. In some examples, the shower head 504 is disposed over stage 506. In other embodiments, the chamber 502 may be oriented horizontally (i.e., rotated 90 degrees from the position in FIG. 7). In some embodiments, the shower head 504 is a gas distribution apparatus, which is configured to provide a processing gas onto the substrate 101 inside a chamber 502. For example, the shower head 50 may include a plurality of openings 512 that are adapted for providing the processing gas flowing from shower head 504 to the substrate 101 inside the chamber 502. The chamber 502 may be used for deposition or etching in semiconductor processing. In some embodiment, it is a deposition apparatus such as a CVD, a plasma enhanced CVD (PECVD), physical vapor deposition (PVD) or atomic layer deposition (ALD) chamber, or any other semiconductor processing chamber.

In some embodiments, an inlet 510 is connected with the shower head 504 and adapted to supply at least one chemical in a gas state from outside chamber 502. In some embodiments, two or more chemicals in a gas state may be supplied through inlet 510. In some embodiments, at least one vacuum system 119 is fluidly coupled to the shower head 504 to provide vacuum in at least one zone of the shower head 504. In some embodiments, the reaction chamber 500 may further include a vacuum port 526 is disposed on chamber 502 in some embodiments. Connected with a vacuum pump with controls, the vacuum port 526 is configured to apply vacuum for the whole chamber 502. The vacuum applied to chamber 502 (between the walls of chamber 502 and the outer surface of shower head 504) may be distinguished from the back vacuum applied to shower head 504 in this disclosure.

Referring now to FIG. 3 and FIG. 7, after the transition metal layer 202 is formed over the insulating layer 102 of the substrate 101 in the reaction chamber 500. A chalcogen-containing fluid 206 is flowed into the reaction chamber 500 through, for example, the inlet 510 of the reaction chamber 500. The material of the chalcogen-containing fluid 206 may include Sulfur (S), Selenium (Se), or Tellurium (Te), hydrogen sulfide (H₂S), (Methyldisulfanyl) methane (DMDS), Hydrogen Selenide (H₂Se), any combination thereof, or the like. Then, a heating process is performed in the reaction chamber 500 over the transition metal layer 202 with the chalcogen-containing fluid 206 to transform the transition metal layer 202 into a 2D material layer 204, i.e., the 2D material layer 204 shown in FIG. 4B, over the substrate 101. In other words, the reaction chamber 500 is heated to higher temperatures (e.g., equal to or greater than 400° C.) while chalcogen-containing fluid (gas) 206, typically hydrogen sulfide (H₂S), flowing into the reaction chamber 500 through the inlet 510 to form the 2D material layer 204, which is a transition metal dichalcogenides (TMDs). In some embodiments, the heating temperature of the heating process is substantially equal to or greater than 400° C. In some embodiments, the 2D material layer 204 includes one or more sub-layers as it is shown in FIG. 4B. The number of sub-layers resulting from the deposition process can be controlled by varying the amount of precursors introduced into the reaction chamber 500 as well as the pressure and/or temperature under which the deposition process is performed.

In accordance with some embodiments of the disclosure, the transition-metal dichalcogenide monolayers are atomically thin semiconductors of the type MX₂, with M being a transition-metal atom (Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), or Palladium (Pd), any combinations thereof, or the like) and X being a chalcogen atom (Sulfur (S), Selenium (Se), or Tellurium (Te), hydrogen sulfide (H₂S), (Methyldisulfanyl) methane (DMDS), Hydrogen Selenide (H₂Se), any combination thereof, or the like). The 2D material layer 204 formed accordingly includes TaS₂, TiS₂, MoS₂, SeS₂, WSe₂, WS₂, TeS₂, or MoSe₂, etc. One layer of M atoms is sandwiched between two layers of X atoms. For example, in the embodiment, Ta is the transition-metal atom Tantalum (Ta) with sulfur (S) as precursor to acuate a sulfidation reaction to form the 2D material layer 204 of TaS₂. For example, an CVD process may be performed using Ta+2S═TaS₂ at a temperature of about 500° C. to about 750° C. For example, in the embodiment, the 2D material layer 204 of TaS₂ may be formed from about 500° C. to about 550° C. Certainly, other materials and processes parameters may be used.

In some embodiments, the 2D material layer 204 may also be doped in some embodiments. For example, in embodiments in which the thin 2D material layer 204 includes WeS₂, a p-type device may be formed by, for example, doping the 2D material layer 204 with NO₂ molecules, which are expected to be absorbed both physically and chemically on top of the WSe₂ surface. The doping may be performed by exposing the 2D material layer 204 to 0.05% NO₂ in N₂ gas for 10 minutes, for example. N-type devices may be formed by doping with, for example, potassium.

In some embodiments, S to Ta ratio of the TaS₂ layer increases from 1.2 to 1.8 by increasing the process temperature from 550° C. to 750° C. That is, chalcogen atom (e.g., S) to transition-metal atom (e.g., Ta) ratio of the transition-metal dichalcogenide (e.g., TaS₂) of the 2D material layer 204 can be adjusted according to the heating temperature. In some embodiments, a thickness of the thin 2D material layer 204 has a thickness of about 0.6 nm to about 3 nm, such as about 0.6 nm. However, the disclosure is not limited thereto. In the embodiment, the sulfidation reaction is exothermic and the heating temperature of the heating process may be about 500° C. to 600° C., and the process may require plasma assist to lower the process temperature.

In accordance with some embodiments of the disclosure, the heating process may be performed while the chalcogen-containing fluid 206, e.g., hydrogen sulfide (H₂S), flowing into the chamber 500 and soaking the transition metal layer 202, e.g., Tantalum (Ta), with the process temperature of about 500° C. to about 750° C. for about 30 minutes. In another embodiment, for reducing thermal budget, two steps of thermal processes may be applied during the forming of the 2D material layer 204. In the embodiment, an annealing process may be performed after the heating process, and the process temperature of the annealing process is higher than the heating temperature of the heating process. For example, the heating process may be performed while the chalcogen-containing fluid, e.g., hydrogen sulfide (H₂S) flowing into the chamber 500 and soaking the transition metal layer 202, e.g., Tantalum (Ta), with the process temperature of about 400° C. for about 10 minutes. Then, the annealing process is performed with the process temperature of about 750° C. for about 10 minutes. That is, by adding the step of annealing process, the duration of the thermal process can be reduced.

Annealing process is a heat treatment that alters the physical and sometimes chemical properties of the material to increase its ductility and reduce its hardness. It involves heating a material above its recrystallization temperature, maintaining a suitable temperature for an appropriate amount of time and then cooling it to room temperature in still air. The annealing process can be used to adjust the material properties from harder and more brittle to softer and more ductile, so as to provides better step coverage over the 3D structure, e.g., the insulating layer 102 with the trenches 104.

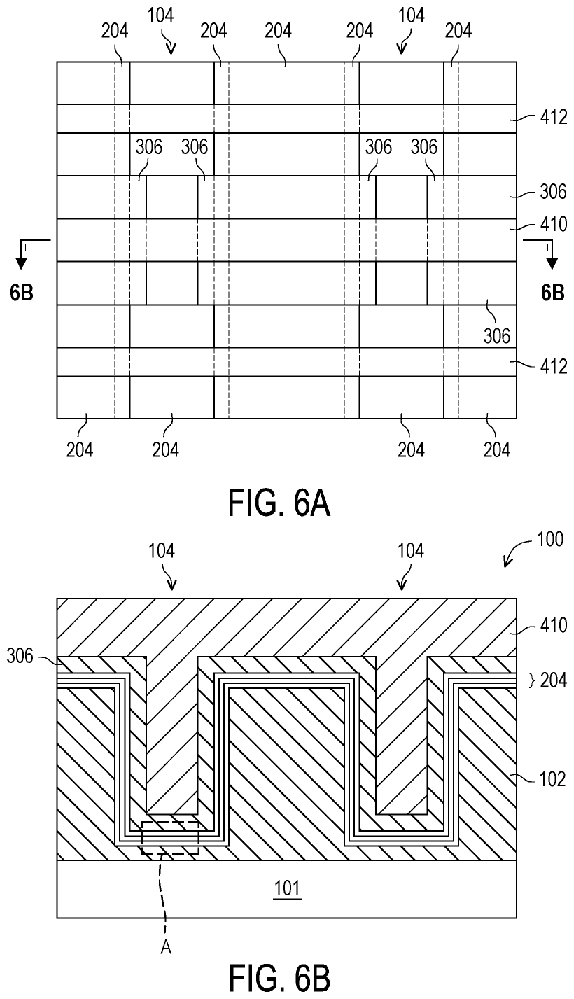

In accordance with some embodiments of the disclosure, the thin layer of 2D material layer 204 is capable of completely (conformally) covering an upper surface of the insulating layer 102, a sidewall of the trench 104, and a bottom surface of the trench 102 and providing good step coverage, low impurity content, and which does not form any voids. In addition, as described in greater detail below, the thin layer of 2D material layer 204 will act as a layer in which the source/drain regions and channel region are formed, thereby forming an ultra-thin body (UTB) semiconductor device (e.g., the semiconductor device 100 in FIG. 6B). The use of the three-dimensional (3D) structures, e.g., insulating layer 102 having the trenches 104, with the 2D material layer 204 allows formation of semiconductor devices having a much smaller footprint. For example, a transistor having the 2D material layer 204 may be formed having a larger gate width while requiring a smaller footprint as compared to other types of transistors. Additionally, the use of the 2D material layer 204 allows the semiconductor devices 100 that provides improved gate control. To be more specific, the 3D structures of the trenches 104 increases the effective area of the 2D material layer 204. As explained in greater detail below, a gate electrode and will be formed over the 2D material layer 204 such that the gate width is increased by the use of the trenches 104, thereby increasing the effective gate width for a given footprint.

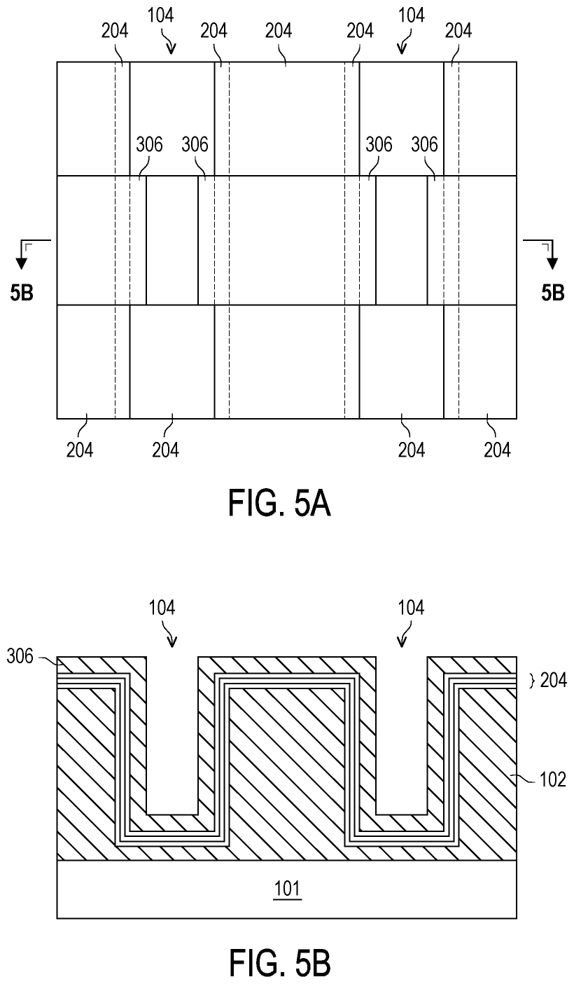

In accordance with some embodiments of the disclosure, referring to FIG. 5A and FIG. 5B, a gate dielectric 306 is formed over a portion of the 2D material layer 204 in accordance with some embodiments. As will be explained in greater detail below, a gate electrode will be formed over the gate dielectric 306. In some embodiments, the gate dielectric 306 includes one or more high-k dielectric layers (e.g., having a dielectric constant greater than 3.9). For example, the gate dielectric 306 may include one or more layers of a metal oxide or a silicate of Hf, Al, Zr, combinations thereof, and multi-layers thereof. Other suitable materials include La, Mg, Ba, Ti, Pb, Zr, in the form of metal oxides, metal alloyed oxides, and combinations thereof. Exemplary materials include MgOₓ, BaTiₓOy, BaSrₓTi_{y}O_{z}, PbTiₓOy, zPbZrₓTi_{y}O_{z}, and the like. The formation methods of the gate dielectric 306 may include molecular-beam deposition (MBD), atomic layer deposition (ALD), PVD, and the like. The gate dielectric 306 may be patterned using photolithography techniques to expose portions of the 2D material layer 204 for forming source/drain contacts as illustrated in FIGS. 5A and 5B. In an embodiment, the gate dielectric 306 may have a thickness of about 1 nm to about 5 nm, for example. In some embodiments, the insulating layer 102 and/or the gate dielectric 306 are formed of high-k dielectric materials. The use of the high-k dielectric materials strongly dampen scattering from Coulombic impurities.

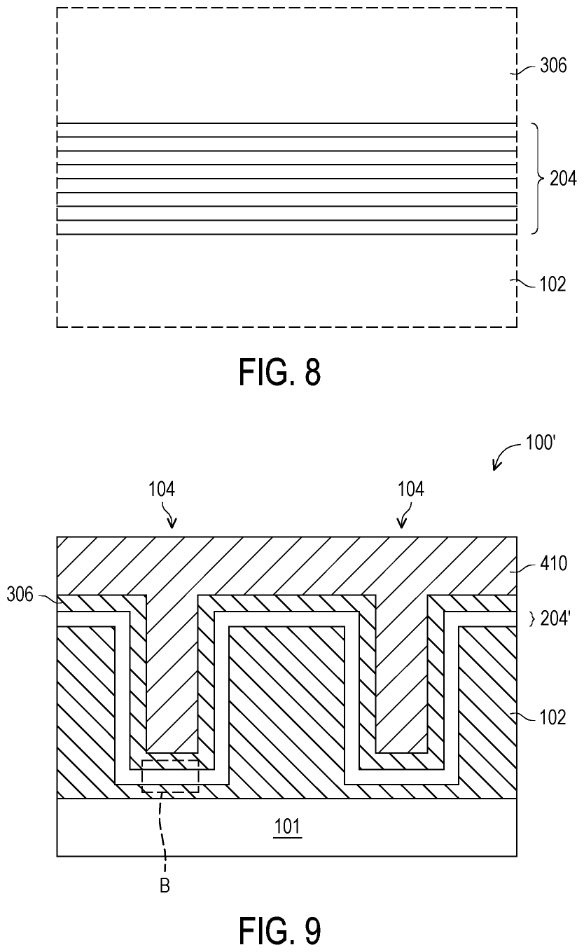

FIG. 8 illustrate a partial enlarged view of the semiconductor device in FIG. 6B. In accordance with some embodiments of the disclosure, referring to FIG. 6A, FIG. 6B and FIG. 8, a gate electrode 410 is formed over the gate dielectric 306 along the sidewall of the trench 107 and a plurality of source/drain contacts 412 is formed over the thin 2D material layer 204 in accordance with some embodiments. In some embodiments, the gate electrode 410 covers (e.g., in contact with) a part of the gate dielectric 306 along the sidewall of the trench 107, while the source/drain contacts 412 covers (e.g., in contact with) a part of the 2D material layer 204 that is not covered by the gate dielectric 306. The gate electrode 410 and the source/drain contacts 412 may be formed of any suitable conductive material. For example, in some embodiments, the gate electrode 410 and the source/drain contacts 412 may be formed of a doped polysilicon, a metal (such as titanium, palladium, tungsten, aluminum, copper, nickel, gold, alloys thereof, combinations thereof, and the like), or the like.

The gate electrode 410 and the source/drain contacts 412 may be formed using any suitable process. For example, in some embodiments the gate electrode 410 and the source/drain contacts 412 may be formed using a gate first process, in which a layer of conductive material is formed over the substrate 101 and patterned to form the gate electrode 410 and the source/drain contacts 412.

As another example, in some embodiments the gate electrode 410 and the source/drain contacts 412 may be formed using a gate last process. Generally, a gate last process forms a sacrificial gate stack. Source/drain regions may be doped, if necessary, using the sacrificial gate stack as a mask for the channel region. A first interlayer dielectric (ILD) layer is formed such that an upper surface of the sacrificial gate stack is exposed. The sacrificial gate stack is then removed, thereby forming an opening in the ILD layer. A gate, such as a metal gate stack, is formed in the opening. In a gate last process, an interfacial layer and the gate dielectric may be formed upon removing the sacrificial gate stack.

The gate electrode 410 and the source/drain contacts 412 are shown for illustrative purposes only and may include multiple other features. For example, work metal function layers may be formed and a composite gate stack may be utilized. As another example, various spacers and liners may be utilized to adjust the source/drain regions for a particular design. The process used to form the gate electrode 410 and the source/drain contacts 412, such as a gate first approach or a gate last approach, may also utilize different structures.

It is noted that FIG. 1A to FIG. 6B and the relevant discussion above disclose a transistor formed in trenches 104 of the insulating layer 102, but the formation of the 2D material layer 204 may also be utilized in different structures. For example, other embodiments may utilize similar processes and materials to form a transistor having the 2D material layer 204 along surfaces of a fin, such as a fin formed between adjacent trenches. In one embodiment, the formation of the 2D material layer 204 may be applied to a semiconductor device having a transistor having vertical channel structures formed along surfaces of a dielectric fin in accordance with some embodiments.

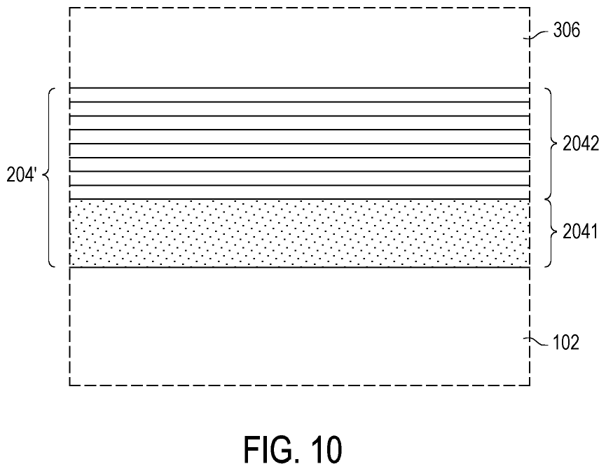

FIG. 9 illustrate a partial cross-sectional view of a semiconductor device according to some embodiments of the present disclosure. FIG. 10 illustrate a partial enlarged view of the semiconductor device in FIG. 9. Referring to FIG. 9 and FIG. 10, in some embodiments, for example, in the embodiment of forming the 2D material layer by performing two steps of thermal processes (e.g., heating process and annealing process), only an upper part of the transition metal layer (e.g., the transition metal layer 202 in FIG. 3) is transformed into the 2D material monolayers, and the lower part of the transition metal layer remains being the transition metal. That is, in some embodiments, there may be a transition metal layer 2041 between the insulating layer 102 and the 2D material layer 2042 of the layer 204′, wherein the transition metal layer 2041 includes Ti, Zr, Hf, V, Nb, Ta, Mo, W, Tc, Re, Co, Rh, Ir, Ni, or Pd, combination thereof, or the like, and the 2D material layer 2042 includes TaS₂, TiS₂, MoS₂, SeS₂, WSe₂, WS₂, TeS₂, MoSe₂, combination thereof, or the like. The disclosure is not limited thereto.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a method for manufacturing a semiconductor device includes the following steps. A transition metal layer is formed over a substrate in a reaction chamber; a chalcogen-containing fluid is flowed into the reaction chamber; and a heating process is performed in the reaction chamber over the transition metal layer with the chalcogen-containing fluid to transform the transition metal layer into a two-dimensional (2D) material layer over the substrate. In an embodiment, a material of the transition metal layer comprises Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), or Palladium (Pd). In an embodiment, a material of the chalcogen-containing fluid comprises Sulfur (S), Selenium (Se), or Tellurium (Te), hydrogen sulfide (H2S), (Methyldisulfanyl) methane (DMDS), Hydrogen Selenide (H2Se). In an embodiment, a heating temperature of the heating process is substantially equal to or greater than 400° C. In an embodiment, the heating process is performed while the chalcogen-containing fluid flows into the reaction chamber. In an embodiment, the method further includes performing an annealing process after the heating process. In an embodiment, a process temperature of the annealing process is higher than the heating temperature of the heating process. In an embodiment, the transition metal layer is formed by physical vapor deposition, chemical vapor deposition, or atomic layer deposition. In an embodiment, the 2D material layer comprises TaS₂, TiS₂, MoS₂, SeS₂, WSe₂, WS₂, TeS₂, or MoSe₂.

In accordance with some embodiments of the disclosure, a method for manufacturing a semiconductor device includes the following steps. A trench is formed in an insulating layer over a substrate; a transition metal layer is formed over the insulating layer; and a transforming process is performed to transform the transition metal layer into a two-dimensional (2D) material layer, wherein the 2D material layer covers an upper surface of the insulating layer, a sidewall of the trench, and a bottom of the trench. In an embodiment, the transition metal layer includes Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), or Palladium (Pd). In an embodiment, the transforming process includes: flowing a chalcogen-containing fluid over the transition metal layer while performing a heating process. In an embodiment, a material of the chalcogen-containing fluid comprises Sulfur (S), Selenium (Se), or Tellurium (Te), hydrogen sulfide (H₂S), (Methyldisulfanyl) methane (DMDS), Hydrogen Selenide (H₂Se). In an embodiment, the transforming process further includes: performing an annealing process after the heating process, wherein a process temperature of the annealing process is higher than the heating temperature of the heating process. In an embodiment, the method further includes: forming a gate dielectric over a portion of the 2D material layer; forming a gate electrode over the gate dielectric along the sidewall of the trench; and forming a plurality of source/drain contacts over the 2D material layer.

In accordance with some embodiments of the disclosure, a semiconductor device includes a substrate, an insulating layer, a 2D material layer, a gate dielectric, a gate electrode, and a plurality of source/drain contacts. The insulating layer is over the substrate, wherein the insulating layer comprises a trench. The 2D material layer covers an upper surface of the insulating layer, a sidewall of the trench, and a bottom of the trench, wherein the 2D material layer includes TaS₂, TiS₂, MoS₂, SeS₂, WSe₂, Ws₂, TeS₂, or MoSe₂. The gate dielectric is over a portion of the 2D material layer. The gate electrode is over the gate dielectric along the sidewall of the trench. The plurality of source/drain contacts cover a part of the 2D material layer. In an embodiment, the 2D material layer includes a plurality of monolayers held together by chemical bonds. In an embodiment, the semiconductor device further includes a transition metal layer between the insulating layer and the 2D material layer, wherein the transition metal layer includes Ti, Zr, Hf, V, Nb, Ta, Mo, W, Tc, Re, Co, Rh, Ir, Ni, or Pd. In an embodiment, the semiconductor device further includes a gate dielectric over a portion of the 2D material layer, a gate electrode over the gate dielectric along the sidewall of the trench, and a plurality of source/drain contacts covering a part of the 2D material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a transition metal layer over a substrate in a reaction chamber;
flowing a chalcogen-containing fluid into the reaction chamber; and
performing a heating process in the reaction chamber over the transition metal layer with the chalcogen-containing fluid to transform the transition metal layer into a two-dimensional (2D) material layer over the substrate.

2. The method as claimed in claim 1, wherein a material of the transition metal layer comprises Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), or Palladium (Pd).

3. The method as claimed in claim 1, wherein a material of the chalcogen-containing fluid comprises Sulfur (S), Selenium (Se), or Tellurium (Te), hydrogen sulfide (H₂S), (Methyldisulfanyl) methane (DMDS), Hydrogen Selenide (H₂Se).

4. The method as claimed in claim 1, wherein a heating temperature of the heating process is substantially equal to or greater than 400° C.

5. The method as claimed in claim 1, wherein the heating process is performed while the chalcogen-containing fluid flows into the reaction chamber.

6. The method as claimed in claim 1, further comprising performing an annealing process after the heating process.

7. The method as claimed in claim 6, wherein a process temperature of the annealing process is higher than the heating temperature of the heating process.

8. The method as claimed in claim 6, wherein the transition metal layer is formed by physical vapor deposition, chemical vapor deposition, or atomic layer deposition.

9. The method as claimed in claim 6, wherein the 2D material layer comprises TaS₂, TiS₂, MoS₂, SeS₂, WSe₂, Ws₂, TeS₂, or MoSe₂.

10. A method for manufacturing a semiconductor device, comprising:
forming a trench in an insulating layer over a substrate;
forming a transition metal layer over the insulating layer; and
performing a transforming process to transform the transition metal layer into a two-dimensional (2D) material layer, wherein the 2D material layer covers an upper surface of the insulating layer, a sidewall of the trench, and a bottom of the trench.

11. The method as claimed in claim 10, wherein the transition metal layer comprises Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), or Palladium (Pd).

12. The method as claimed in claim 10, wherein the transforming process comprises:
flowing a chalcogen-containing fluid over the transition metal layer while performing a heating process.

13. The method as claimed in claim 12, wherein a material of the chalcogen-containing fluid comprises Sulfur (S), Selenium (Se), or Tellurium (Te), hydrogen sulfide (H₂S), (Methyldisulfanyl) methane (DMDS), Hydrogen Selenide (H₂Se).

14. The method as claimed in claim 12, wherein the transforming process further comprises:
performing an annealing process after the heating process, wherein a process temperature of the annealing process is higher than the heating temperature of the heating process.

15. The method as claimed in claim 10, wherein the 2D material layer comprises TaS₂, TiS₂, MoS₂, SeS₂, WSe₂, Ws₂, TeS₂, or MoSe₂.

16. The method as claimed in claim 10, further comprising:
forming a gate dielectric over a portion of the 2D material layer;
forming a gate electrode over the gate dielectric along the sidewall of the trench; and
forming a plurality of source/drain contacts over the 2D material layer.

17. A semiconductor device, comprising:
a substrate;
an insulating layer over the substrate, wherein the insulating layer comprises a trench;
a 2D material layer covering an upper surface of the insulating layer, a sidewall of the trench, and a bottom of the trench, wherein the 2D material layer comprises TaS₂, TiS₂, MoS₂, SeS₂, WSe₂, Ws₂, TeS₂, or MoSe₂.

18. The semiconductor device as claimed in claim 17, wherein the 2D material layer comprises a plurality of monolayers held together by chemical bonds.

19. The semiconductor device as claimed in claim 17, further comprising a transition metal layer between the insulating layer and the 2D material layer, wherein the transition metal layer comprises Ti, Zr, Hf, V, Nb, Ta, Mo, W, Tc, Re, Co, Rh, Ir, Ni, or Pd.

20. The semiconductor device as claimed in claim 17, further comprising:
a gate dielectric over a portion of the 2D material layer;
a gate electrode over the gate dielectric along the sidewall of the trench; and
a plurality of source/drain contacts covering a part of the 2D material layer.
